(19) United States
(12) Patent Application Publication
(10) Pub. No.: US 2015/0108313 A1
(43) Pub. Date: Apr. 23, 2015

(54) MOBILE DEVICE STAND

(71) Applicant: ALEX KIM LEUNG, T.K.O., HONG KONG (CN)

(72) Inventor: ALEX KIM LEUNG, T.K.O., HONG KONG (CN)

(21) Appl. No.: 14/056,757

(22) Filed: Oct. 17, 2013

(51) Int. Cl. F16F 1/02; H05K 5/02

(52) U.S. Cl. CPC F16F 1/025; F16F 1/021; H05K 5/0204
USPC 248/351

(57) ABSTRACT

A shape-changing mobile device stand is disclosed. The stand includes a mount, such as a case, for receiving a mobile device and a shape-changing tab connected to the mount. The tab may have a flat shape. When pressure is applied to one end of the tab, it changes shape to have a curved shape, which may support the mount and mobile device in portrait or landscape orientation.

### BACKGROUND

The embodiments herein relate generally to stands and cases with integral stands for mobile devices, such as smartphones, tablets, MP3 players, ebook readers, and so on.

Currently, only a handful of mobile devices include an integrated or built-in stand. User with a device that lacks a built-in stand must use their hands to support the device or purchase a separate stand. These stands, whether built-in or added through an accessory, are bulky and difficult to operate.

Current mobile device stands have several moving parts, including panels and hinges that must be folded and unfolded to deploy and retract the stand. These stands add bulk, are difficult to operate, and are unattractive. Few, if any, can be operated with one hand.

### SUMMARY

According to one embodiment of the present disclosure, a system for supporting a mobile device on a surface with a shape-changing tab includes a mount configured to receive a mobile device and a tab connected to the mount. The tab includes a connected end and a free end, and it is connected to the mount near the connected end. The tab also includes a curved shape and a flat shape. The tab is configured to change from the flat shape to the curved shape when pressure is applied near the connected end.

Optionally, the mobile device may include an electronic appliance. Additionally, the mobile device may include at least one of a portable electronic appliance, a laptop computer, a tablet computer, a tabletop computer, a digital camera, a smartphone, a tablet, an ebook reader, an MP3 player, a portable television, a portable video player, and a portable DVD player. The tab may include a core, and the core may include a curved shape and a flat shape. The tab may also include a flexible covering attached to the core. The core may include copper that has been heat-treated to form a curved shape. The copper may be configured to be changed into a flat shape. The copper may also be configured to change from the flat shape to the curved shape when pressure is applied near an end of the copper.

### BRIEF DESCRIPTION OF THE FIGURES

The detailed description of some embodiments of the present invention is made below with reference to the accompanying figures, wherein like numerals represent corresponding parts of the figures.

FIG. 1 shows a perspective view of one embodiment of the present invention, shown in use with an exemplary mobile device in a landscape orientation.

FIG. 2 shows a perspective view of the embodiment of the present invention of FIG. 1.

FIG. 3 shows a perspective view of an exemplary tab from the embodiment of the present invention of FIG. 1, detached from the case for clarity.

FIG. 4 shows a section view of the embodiment of the present invention of FIG. 1, taken along line 4-4 in FIG. 3.

FIG. 5 shows a section view of the embodiment of the present invention of FIG. 1, taken along line 5-5 in FIG. 3.

FIG. 6 shows a side view of the embodiment of the present invention of FIG. 1, showing a user pressing the tab.

FIG. 7 shows a side view of the embodiment of the present invention of FIG. 1, illustrating the tab in a curved shaped.

FIG. 8 shows a perspective view of the embodiment of the present invention of FIG. 1, shown in use with an exemplary mobile device in a portrait orientation.

FIG. 9 shows a side view of the embodiment of the present invention of FIG. 1, shown in use with an exemplary mobile device in a portrait orientation.

### DETAILED DESCRIPTION OF CERTAIN EMBODIMENTS

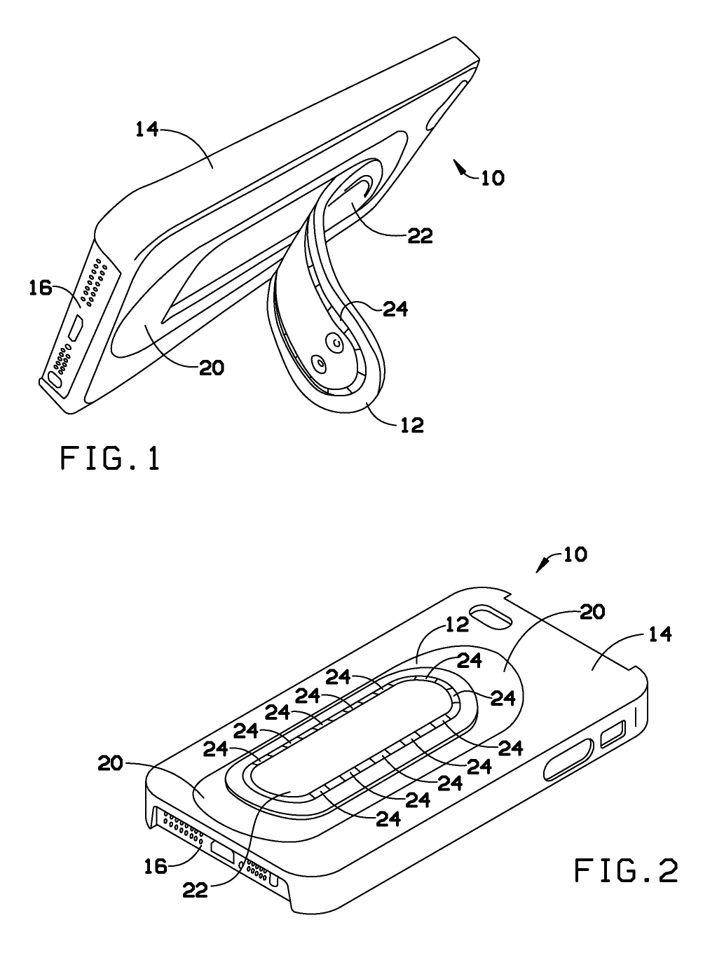

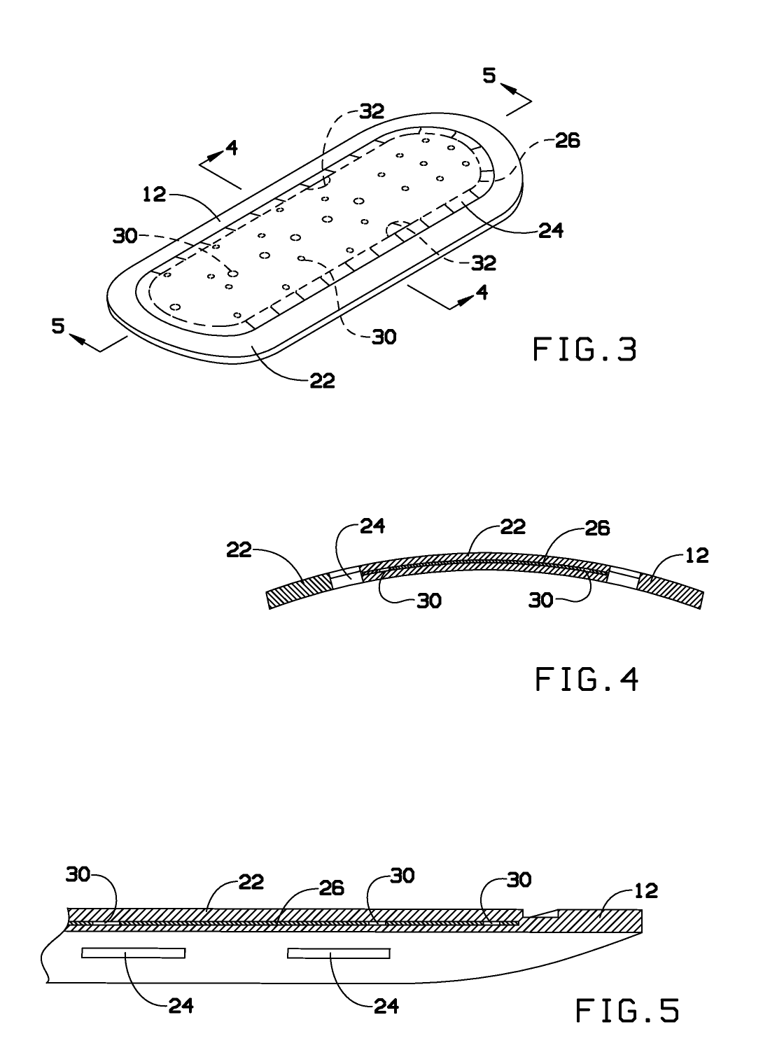

By way of example, and referring to FIGS. 1-5, one embodiment of the present invention comprises a system 10 for supporting a mobile device on a surface. As used herein, the term “mobile device” means a portable electronic appliance, including without limitation, a laptop computer, a tablet computer, a tabletop computer, a digital camera, a smartphone, a tablet, an ebook reader, an MP3 player, a portable television, a portable video player, a portable DVD player, or the like. The system 10 may include a tab 12 and a mount 14 for receiving a mobile device 16. The mount 14 may include, e.g., a case that removably attaches to the mobile device 16, an easel or stand on which a mobile device 16 is placed, or the like. While the present invention is illustrated, e.g. in FIG. 1, with an exemplary mobile device case and cover, component configuration and design may be modified, and such modifications may be made without departing from the spirit and scope of the present invention.

The tab 12 may include the ability to change its shape. For example, the tab 12 may include two shapes, such as, e.g., a flat shape and a curved shape. In a flat shape, the tab 12 may fit or lie in a cradle 20 in the mount 14. The tab 12 may include a cover 22 made of plastic or another flexible material, and the cover 22 may include one or more openings 24, which may allow the cover to accommodate a change in shape.

The tab 12 may include a core 26. The core 26 may provide rigidity to the tab 12, and the core 26 may control the shape of the tab 12. For example, the core 26 may include copper that has been heat-threated to form a curve shape. The core 26 may include one or more perforations 30 and/or notches 32, which may allow the core 26 to accommodate a change in shape.

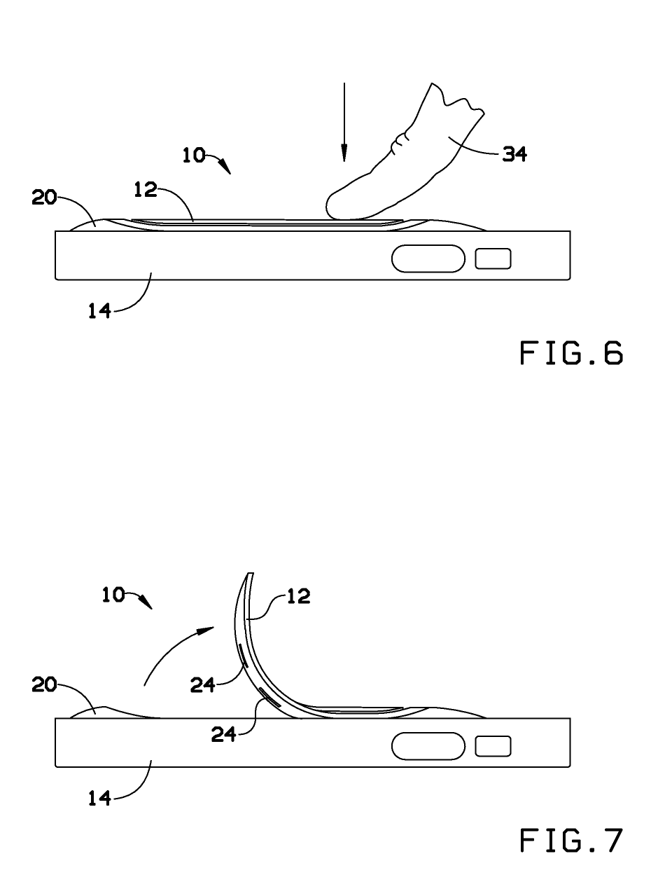

Referring to FIGS. 6 and 7, the tab 12 may have a flat shape. For example, the core 26 may include copper that has been heat-threated to form a curve shape, yet has sufficient elasticity to be pressed into a flat shape, as shown, e.g., in FIG. 6. The tab 12 may be attached or connected to the mount 14 near one end of the tab 12. When pressure is applied to this end of the tab 12 with, e.g., a finger 34, the tab 12 may assume a curved shape, as shown, e.g., in FIG. 7.

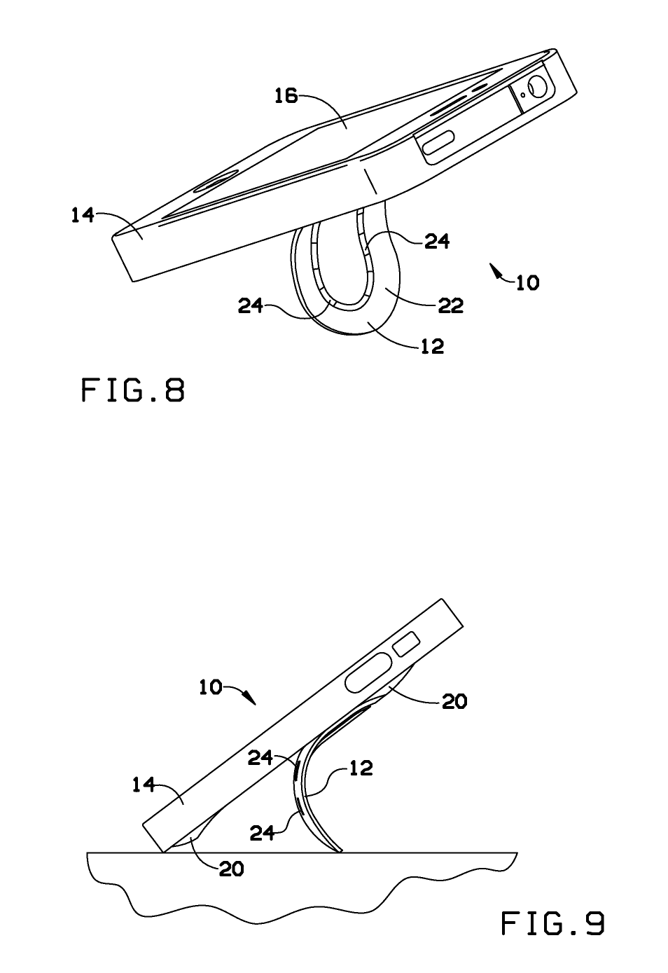

Referring to FIGS. 8 and 9, the mobile device 16 and/or mount 14 may include a longer edge and a shorter edge. When the tab 12 is in a deployed or curved shape, it may support the mobile device 16 and/or mount 14 resting on either the longer edge or shorter. When the mobile device 16 and/or mount 14 is resting on the shorter edge, it may be regarded as being in a portrait orientation. When the mobile device 16 and/or mount 14 is resting on the longer edge, it may be regarded as being in a landscape orientation.

Persons of ordinary skill in the art may appreciate that numerous design configurations may be possible to enjoy the functional benefits of the inventive systems. Thus, given the wide variety of configurations and arrangements of embodiments of the present invention the scope of the present invention is reflected by the breadth of the claims below rather than narrowed by the embodiments described above.

What is claimed is:

1. A system for supporting a mobile device on a surface with a shape-changing tab, the system comprising:
a mount configured to receive a mobile device; and
a tab comprising a connected end and a free end and connected to the mount near the connected end, the tab further comprising a flat shape and a curved shape, the tab configured to change from the flat shape to the curved shape when pressure is applied near the connected end.

2. The system of claim 1, wherein the mobile device comprises an electronic appliance.

3. The system of claim 1, wherein the mobile device comprises at least one of a portable electronic appliance, a laptop computer, a tablet computer, a tabletop computer, a digital camera, a smartphone, a tablet, an ebook reader, an MP3 player, a portable television, a portable DVD player, and a portable video player.

4. The system of claim 1, wherein the tab comprises a core comprising a curved shape and a flat shape, the tab further comprising a flexible covering attached to the core.

5. The system of claim 4, wherein the core comprises copper that has been heat-treated to form a curved shape, the copper configured to be changed into a flat shape, the copper further configured to change from the flat shape to the curved shape when pressure is applied near an end of the copper.
